(19) United States
(12) Patent Application Publication
(10) Pub. No.: US 2006/0005088 A1
(43) Pub. Date: Jan. 5, 2006

(54) System and method for testing artificial memory

(75) Inventors: Xin Zeng, Shenzhen (CN); Tang He, Shenzhen (CN)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD., Tu-Cheng City (TW)

(21) Appl. No.: 11/024,506

(22) Filed: Dec. 29, 2004

(30) Foreign Application Priority Data
Jun. 30, 2004 (TW) 93119345

(51) Int. Cl. G11C 29/00; G01R 31/28

(52) U.S. Cl. 714/724

(57) ABSTRACT

A system for testing an artificial memory includes a monitor (10), a driver (20), and an executing means (30). The monitor includes a command line interface (101) for inputting commands and parameters. The driver includes a command line editor (201), which is adapted to be activated before the command line interface is used; a command translator (202) for invoking corresponding subprograms according to the input commands and parameters; an error flag (203) for indicating whether any error occurred during the testing; and an error counter (204) for counting the number of times any error occurred during the testing. The executing means is for testing the memory with reading/writing of sequence bit strings, and returning test results to the monitor via the driver. A related method for testing an artificial memory is also provided.

### BACKGROUND OF THE INVENTION

1. Field of the Invention

The present invention relates to a system and method for testing an artificial memory, and more specifically, to a system and method for testing a memory in a computer diagnostic process.

2. Description of the Related Art

Testing a newly manufactured computer memory is a necessary quality control procedure performed before the memory is shipped to a customer. The memory may be volatile or non-volatile, such as an SDRAM, a DDR (Double Data Rate) RAM, a Flash Memory, and so on.

In a conventional method of testing a memory, specialized equipment is used. The equipment detects the integrity of data during the processes of reading/writing the data from/to the memory, to determine whether the memory is operating correctly. Such testing includes random testing to memory addresses, blocks, storage areas and self-refresh.

The above-described conventional method of testing a memory is an exhaustive task, and takes a lot of time. In practice, when memories are mass manufactured, the yield of satisfactory memories tends to vary little. That is, most of the memories produced have satisfactory quality. The conventional method is only suitable for testing a single memory in a lab, but not for mass testing of memories by a manufacturer or supplier. Accordingly, there is a need for a system and method to simplify the procedures for testing a memory and thereby increase the efficiency of mass testing of memories.

### SUMMARY OF THE INVENTION

It is therefore an objective of the present invention is to provide a system for readily testing a memory.

Another objective of the present invention is to provide a method for readily testing a memory.

In order to accomplish the above-mentioned first objective, a preferred embodiment of a system for testing a memory comprises a monitor, a driver and an executing means. The monitor comprises a command line interface for inputting of commands and parameters by users. The driver comprises: a command line editor, which is adapted to be activated before the command line interface of the monitor is used; a command translator for invoking corresponding subprograms according to the input commands and parameters; an error flag for indicating whether any error occurred during a test of the memory; and an error counter for counting the number of times any error occurred during one or more tests of the memory. The executing means is for testing the memory with reading/writing of sequence bit strings, and returning test results to the monitor via the driver.

In order to accomplish the above-mentioned second objective, a method for testing a memory comprises the steps of: (1) activating a command line editor of a driver; (2) inputting commands and parameters via a command line interface of a monitor; (3) invoking corresponding subprograms according to the input commands and parameters by way of a command translator of the driver; (4) executing the subprograms to thereby test the memory, by way of an executing means; and (5) returning one or more test results to the monitor via the driver.

Step (4) further comprises the steps of: (4-1) setting an address range and a total number of times that testing of the memory is to be performed; (4-2) filling the memory with a sequence bit string (such as 0×55AA55AA); (4-3) reading the sequence bit string from the memory, and determining whether the written and read data match each other; (4-4) setting an error flag to “1,” if the written and read data do not match; (4-5) determining whether the error flag is “1,” and increasing an error count by one and resetting the error flag to “0” if the error flag is “1;” (4-6) determining whether the number of times that the memory has been tested equals the predetermined total number of times that testing is to be performed; and (4-7) returning the count of the error counter as the test result if the two numbers in the above step are the same, or repeating steps (4-2) to step (4-6) if the two numbers in the above step are not the same.

The system and method of the present invention provide testing of the quality of a memory by utilizing simple reading/writing procedures. Therefore the testing is speedy and efficient.

Other objects, advantages and novel features of the invention will be drawn from the following detailed description with reference to the attached drawings, in which:

### BRIEF DESCRIPTION OF THE DRAWINGS

FIG. 1 is a block diagram of the system for testing a memory in accordance with the preferred embodiment of the present invention;

FIG. 2 is a flowchart of a preferred method for testing a memory in accordance with the present invention; and

FIG. 3 is a flowchart of exemplary details of one step of the method of FIG. 2, namely executing invoked subprograms to thereby test the memory.

### DETAILED DESCRIPTION OF PREFERRED EMBODIMENTS OF THE INVENTION

Hereinafter, a preferred embodiment and method of the present invention will be described. However, the scope of the present invention is not to be taken as limited to the described embodiment and method.

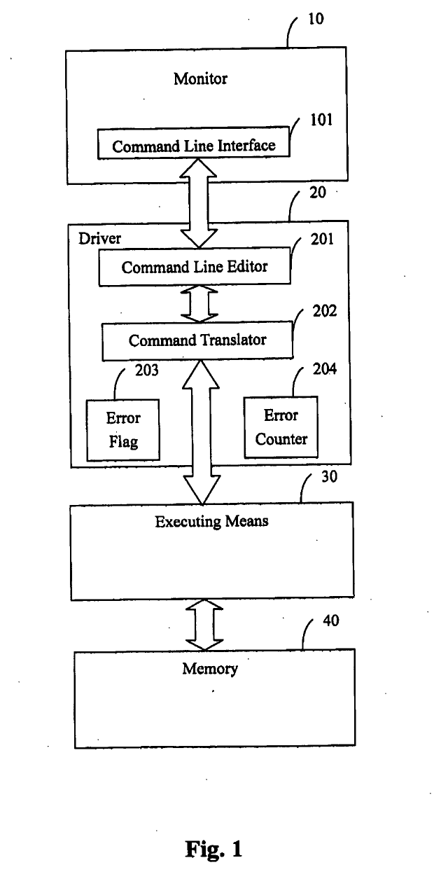

FIG. 1 is a block diagram of a system for testing a memory 40 in accordance with the preferred embodiment of the present invention. The system comprises a monitor 10, a driver 20, and an executing means 30. The monitor 10 comprises a command line interface 101 for inputting commands and parameters. The driver 20 comprises a command line editor 201, a command translator 202 for invoking subprograms according to input commands and parameters, an error flag 203 for indicating an error event when an error has occurred while testing the memory 40, and an error counter 204 for counting the number of times an error occurs while testing the memory 40. Users have to activate the command line editor 201 before using the command line interface 101 of the monitor 10, in order to limit the maximum length of input command characters to 255. The executing means 30 is for testing the memory 40 with reading/writing tests, and returning test results to the monitor 10 via the driver 20. The executing means 30 may, for example, be a router with a MIPS (Million Instruction Per Second) CPU inside.

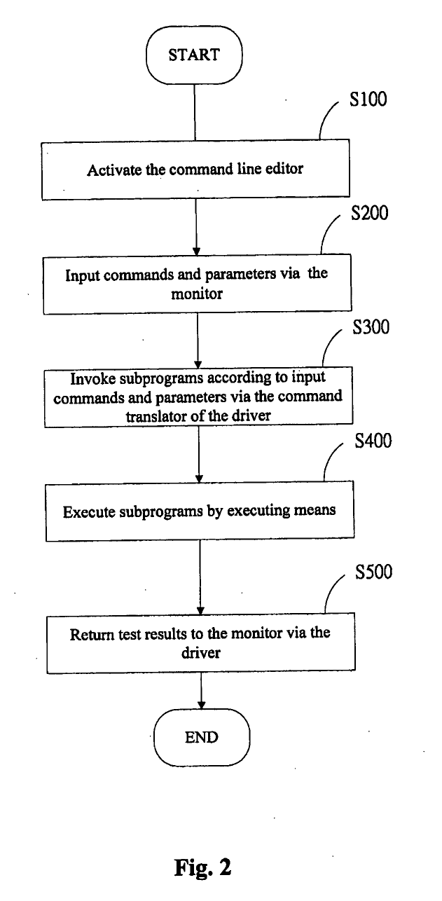

FIG. 2 is a flowchart of the preferred method for testing the memory 40 in accordance with the present invention. At step S100, users activate the command line editor 201 of the driver 20 before using the command line interface 101 of the monitor 10. At step S200, users input commands and parameters via the monitor 10, the parameters including an address range and a total number of times that testing of the memory 40 is to be performed. At step S300, the command translator 202 of the driver 20 invokes corresponding subprograms according to the input commands and parameters. At step S400, the executing means 30 executes the invoked subprograms to thereby test the memory 40. At step S500, when the testing procedure is completed, the executing means 30 returns test results to the monitor 10 via the driver 20.

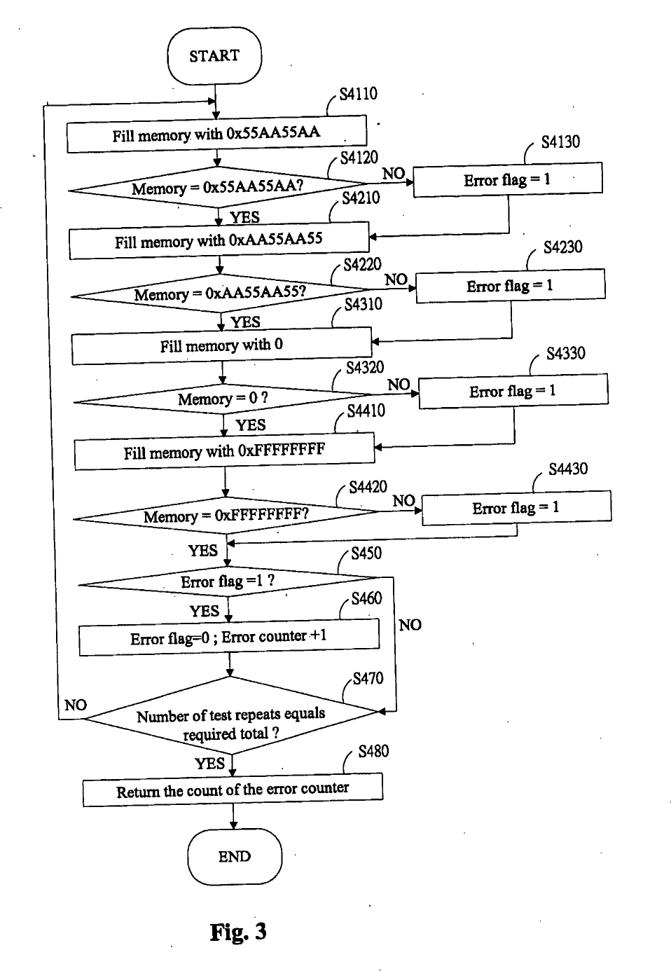

FIG. 3 is a flowchart of exemplary details of step S400 of FIG. 2, namely executing the invoked subprograms to thereby test the memory 40.

At step S4110, the executing means 30 fills the memory 40 with 0×55AA55AA, and then the memory 40 is read. At step S4120, the executing means 30 determines whether the read data are 0×55AA55AA. If the written and read data do not match each other, at step S4130, the executing means 30 sets the error flag 203 to “1,” whereupon the procedure goes to step S4210. Otherwise, the procedure goes to step S4210 directly.

At step S4210, the executing means 30 fills the memory 40 with 033 AA55AA55, and then the memory 40 is read. At step S4220, the executing means 30 determines whether the read data are 0×AA55AA55. If the written and read data do not match each other, at step S4230, the executing means 30 sets the error flag 203 to “1,” whereupon the procedure goes to step S4310. Otherwise, the procedure goes to step S4310 directly.

At step S4310, the executing means 30 fills the memory 40 with 0, and then the memory 40 is read. At step S4320, the executing means 30 determines whether the read data/datum are/is 0. If the written and read data do not match each other, at step S4330, the executing means 30 sets the error flag 203 to “1,” whereupon the procedure goes to step S4410. Otherwise, the procedure goes to step S4410 directly.

At step S4410, the executing means 30 fills the memory 40 with 0×FFFFFFFF, and then the memory 40 is read. At step S4420, the executing means 30 determines whether the read data are 0×FFFFFFFF. If the written and read data do not match each other, at step S4430, the executing means 30 sets the error flag 203 to “1,” whereupon the procedure goes to step S450. Otherwise, the procedure goes to step S450 directly.

At step S450, the executing means 30 determines whether the error flag 203 is “1.” If the error flag 203 is “1,” at step S460, one or more errors have occurred during the testing. The executing means 30 increases a count of the error counter 204 by one and resets the error flag to “0,” whereupon the procedure goes to step S470. If the error flag 203 is “0,” no error has occurred during the testing, and the procedure goes to step S470 directly.

At step S470, the executing means 30 determines whether the number of times that the memory 40 has been tested equals the predetermined total number of times that testing of the memory 40 is to be performed. If the two numbers are not equal, the procedure returns to step S4110 so that testing of the memory 40 is repeated. If and when the two numbers are equal, at step S480, the executing means 30 ends the testing, and returns the count of the error counter 204 as the test results.

Although only a preferred embodiment and a preferred method of the present invention have been described in detail above, it will be apparent to those skilled in the art that various modifications are possible without departing from the inventive concepts herein. Therefore the invention is not limited to the above-described embodiment and method, but rather has a scope defined by the appended claims and allowable equivalents thereof.

What is claimed is:

1. A system for testing an artificial memory, comprising:
a monitor comprising a command line interface for inputting commands and parameters;
a driver comprising a command line editor and a command translator, said command line editor being adapted to be activated before said command line interface of said monitor is used, said command translator being for invoking corresponding subprograms according to said input commands and parameters; and
an executing means for testing the memory and returning test results to said monitor via said driver.

2. The system according to claim 1, wherein a maximum length of commands input to said command line editor is 255 characters.

3. The system according to claim 1, wherein said driver further comprises an error flag for indicating whether any error occurred during a test of the memory.

4. The system according to claim 1, wherein said driver further comprises an error counter for counting the number of times any error occurred during one or more tests of the memory.

5. A method for testing an artificial memory, the method comprising the steps of: activating a command line editor of a driver;
inputting commands and parameters via a command line interface of a monitor;
invoking corresponding subprograms according to the input commands and parameters by way of a command translator of said driver;
executing the subprograms to thereby test the memory, by way of an executing means; and
returning one or more test results to said monitor via said driver.

6. The method according to claim 5, wherein said parameters comprises an address range and a total number of times that testing of the memory is to be performed.

7. The method according to claim 6, wherein the step of executing the subprograms comprises the steps of:
filling the memory with a sequence bit string, reading said sequence bit string from the memory, and determining whether the written and read data match each other;
setting an error flag to “1,” if the written and read data of the above step do not match each other;
determining whether said error flag is “1;”
increasing an error count by one and resetting said error flag to “0.” if said error flag is “1;”
determining whether the number of times that the memory has been tested equals a predetermined total number of times that testing of the memory is to be performed;
repeating the above steps starting with the filling of the memory with a sequence bit string, if the two numbers in the above step are not equal; and
returning the error count as a test result, if the two numbers in the above step are equal.

8. The method according to claim 7, wherein said sequence bit string is selected from the group consisting of 0×55AA55AA, 0×AA55AA55, 0, and 0×FFFFFFFF.

9. A method for testing an artificial memory, the method comprising the steps of:
activating a command line editor;
retrieving commands and parameters related to said testing via said command line editor;
executing said testing according to said commands and parameters; and
reporting testing results.

10. The method according to claim 9, further comprising the step of invoking subprograms to execute said testing according to said commands and parameters before said executing step.

11. The method according to claim 9, further comprising the step of providing a user-approachable command line interface for inputting said commands and parameters.
